(19) United States
(12) Patent Application Publication
(10) Pub. No.: US 2024/0079308 A1
(43) Pub. Date: Mar. 7, 2024

(54) SEMICONDUCTOR PACKAGE ASSEMBLY

(71) Applicant: MEDIATEK INC., Hsinchu City (TW)

(72) Inventor: Che-Hung KUO, Hsinchu City (TW)

(21) Appl. No.: 18/365,259

(22) Filed: Aug. 4, 2023

Related U.S. Application Data
(60) Provisional application No. 63/374,608, filed on Sep. 6, 2022.

(51) Int. Cl. H01L 23/498; H01L 23/00; H01L 23/538; H01L 25/10; H01L 25/16; H10B 80/00

(52) U.S. Cl. CPC H01L 23/49838; H01L 23/49816; H01L 23/5385; H01L 23/5386; H01L 24/08; H01L 25/105; H01L 25/162; H01L 25/165; H10B 80/00; H01L 24/48; H01L 2224/08235; H01L 2224/48227; H01L 2225/1023; H01L 2225/1041; H01L 2225/1058; H01L 2924/14361

(57) ABSTRACT

A semiconductor package assembly is provided. The semiconductor package assembly includes a first semiconductor die, a second semiconductor die and third semiconductor die. The first semiconductor die and the second semiconductor die are arranged side-by-side. The first semiconductor die includes a first interface and a second interface. The first interface is arranged on a first edge of the first semiconductor die. The second interface is arranged on a second edge of the first semiconductor die that is close to the second semiconductor die and connected to the first edge. The third semiconductor die is stacked on the first semiconductor die and the second semiconductor die, wherein the third semiconductor die is electrically connected to the first semiconductor die by the first interface, and wherein the first semiconductor die is electrically connected to the second semiconductor die by the second interface.

### CROSS REFERENCE TO RELATED APPLICATIONS

This application claims the benefit of U.S. Provisional Application No. 63/374,608, filed Sep. 6, 2022, the entirety of which is incorporated by reference herein.

### BACKGROUND OF THE INVENTION

### Field of the Invention

The present invention relates to a semiconductor package assembly, and, in particular, to an interface floorplan for a package-on-package (PoP) semiconductor package.

### Description of the Related Art

With the increasing demand for smaller devices with more functionality, package-on-package (PoP) technology has become increasingly popular. PoP technology vertically stacks two or more packages and minimizes the track lengths between different components, such as a controller and a memory device. This provides better electrical performance, since shorter routing of interconnections yields faster signal propagation and reduced noise and cross-talk defects.

Although existing semiconductor package assemblies are generally adequate, they are not satisfactory in every respect. For example, it is challenging to fulfill the channel requirements for integrating different components into a package. Therefore, there is a need to further improve semiconductor package assemblies to provide flexibility in channel design.

### BRIEF SUMMARY OF THE INVENTION

An embodiment of the present invention provides a semiconductor package assembly. The semiconductor package assembly includes a first semiconductor die, a second semiconductor die and third semiconductor die. The first semiconductor die and the second semiconductor die are arranged side-by-side. The first semiconductor die includes a first interface and a second interface. The first interface is arranged on a first edge of the first semiconductor die. The second interface is arranged on a second edge of the first semiconductor die that is close to the second semiconductor die and connected to the first edge. The third semiconductor die is stacked on the first semiconductor die and the second semiconductor die, wherein the third semiconductor die is electrically connected to the first semiconductor die by the first interface, and wherein the first semiconductor die is electrically connected to the second semiconductor die by the second interface.

An embodiment of the present invention provides a semiconductor package assembly. The semiconductor package assembly includes a fan-out package and a memory package. The fan-out package includes a first semiconductor die, a second semiconductor die and through via (TV) interconnects. The first semiconductor die includes a first interface and a second interface. The first interface is arranged on a first edge of the first semiconductor die. The second interface is arranged on a second edge of the first semiconductor die that is close to the second semiconductor die and adjacent to the first edge. The through via (TV) interconnects are disposed beside the first semiconductor die and the second semiconductor die and are arranged on a first package edge of the fan-out package corresponding to the first edge of the first semiconductor die. The memory package is stacked on the fan-out package and electrically connected to the second semiconductor die by the TV interconnects, the first interface and the second interface. In addition, an embodiment of the present invention provides a semiconductor package assembly. The semiconductor package assembly includes a bottom package and a top package. The bottom package includes a first semiconductor die, a second semiconductor die and through via (TV) interconnects. The first semiconductor die includes a first interface, a second interface and a third interface. The first interface is arranged on a first edge of the first semiconductor die. The second interface is arranged on a second edge of the first semiconductor die that is close to the second semiconductor die and connected to the first edge. The third interface is arranged on a third edge of the first semiconductor die connected to the first edge and opposite the second edge. The through via (TV) interconnects are disposed beside the first semiconductor die and the second semiconductor die and are arranged on a first package edge of the first package corresponding to the first edge of the first semiconductor die. The top package is stacked on the bottom package and electrically connected to the first interface of the first semiconductor die by the TV interconnects and the first interface rather than the second interface.

### BRIEF DESCRIPTION OF THE DRAWINGS

The present invention can be more fully understood by reading the subsequent detailed description and examples with references made to the accompanying drawings, wherein:

FIG. 1A is a cross-sectional view of a semiconductor package assembly in accordance with some embodiments of the disclosure;

FIG. 1B is a cross-sectional view of a semiconductor package assembly in accordance with some embodiments of the disclosure;

FIGS. 2 and 3 are perspective bottom views of a semiconductor package assembly in accordance with some embodiments of the disclosure, showing the arrangement of interfaces of semiconductor dies and through via (TV) interconnects of a bottom package and the arrangement of conductive structures of a top package stacked on the bottom package;

FIGS. 4 and 5 are perspective bottom views of a semiconductor package assembly in accordance with some embodiments of the disclosure, showing the arrangement of interfaces of semiconductor dies and through via (TV) interconnects of a bottom package and the arrangement of conductive structures of a top package stacked on the bottom package;

FIGS. 6 and 7 are perspective bottom views of a semiconductor package assembly in accordance with some embodiments of the disclosure, showing the arrangement of interfaces of semiconductor dies and through via (TV) interconnects of a bottom package and the arrangement of conductive structures of a top package stacked on the bottom package; and

FIGS. 8 and 9 are perspective bottom views of a semiconductor package assembly in accordance with some embodiments of the disclosure, showing the arrangement of interfaces of semiconductor dies and through via (TV) interconnects of a bottom package and the arrangement of conductive structures of a top package stacked on the bottom package.

### DETAILED DESCRIPTION OF THE INVENTION

The following description is made for the purpose of illustrating the general principles of the invention and should not be taken in a limiting sense. The scope of the invention is best determined by reference to the appended claims.

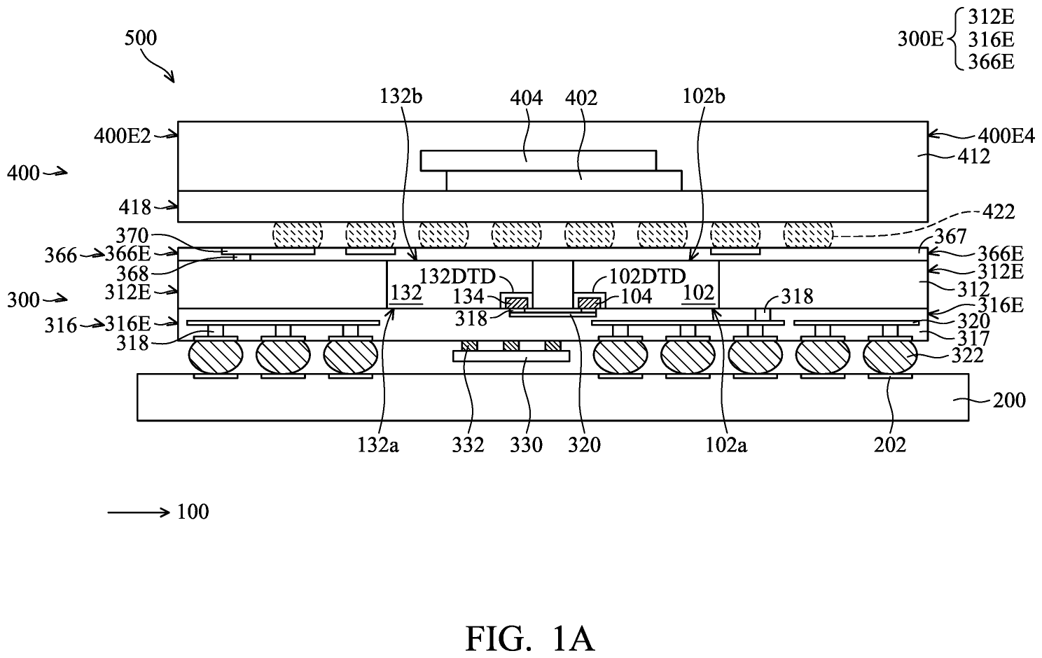

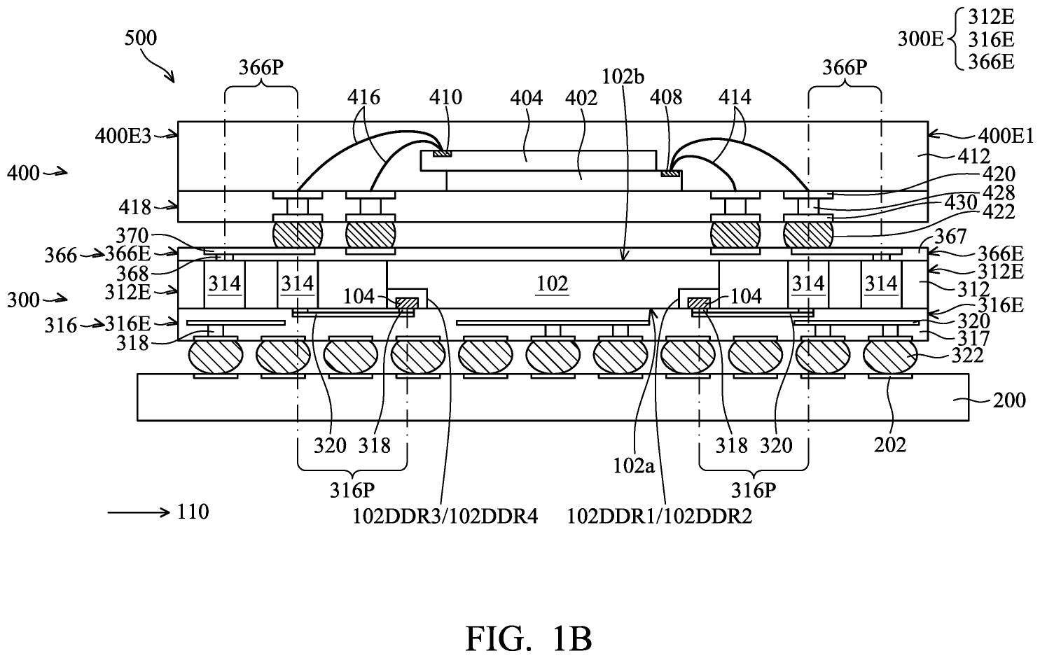

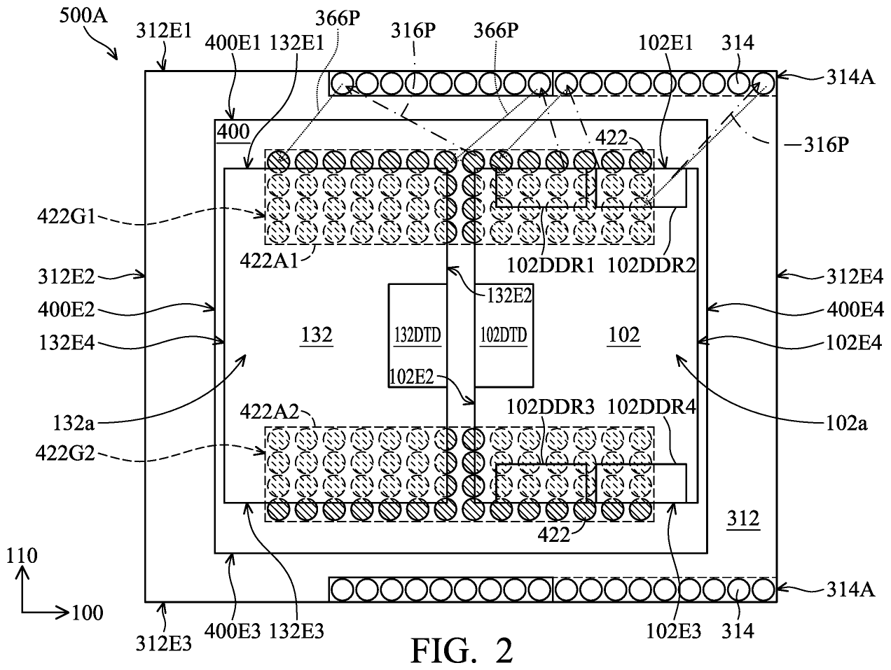

FIGS. 1A and 1B are cross-sectional views of a semiconductor package assembly 500 (including semiconductor package assemblies 500A-500H shown in FIGS. 2-9) along directions 100 and 110 substantially parallel orthogonal edges of the semiconductor package assembly in accordance with some embodiments of the disclosure. In some embodiments, the semiconductor package assembly 500 is a three-dimensional (3D) package-on-package (POP) semiconductor package assembly. The semiconductor package assembly 500 may include at least two vertically stacked wafer-level semiconductor packages mounted on a base 200. As shown in FIG. 1, in some embodiments, the semiconductor package assembly 500 includes a bottom package 300 and a top package 400 vertically stacked on the bottom package 300. In some embodiments, the bottom package 300 comprises a fan-out package such as a system-on-chip (SOC) package. The top package 400 comprises a memory package such as a dynamic random access memory (DRAM) package.

As shown in FIGS. 1A and 1B, the base 200, for example a printed circuit board (PCB), may be formed of polypropylene (PP), Pre-preg, FR-4 and/or other epoxy laminate material. It should also be noted that the base 200 can be a single layer or a multilayer structure. A plurality of pads 202 and/or conductive traces (not shown) is disposed on the base 200. In one embodiment, the conductive traces may comprise signal trace segments or ground trace segments, which are used for the input/output (I/O) connections of the bottom package 300 and the top package 400. Also, the bottom package 300 is mounted directly on the conductive traces. In some other embodiments, the pads 202 are disposed on the base 200, connected to different terminals of the conductive traces. The pads 202 are used for the bottom package 300 that is mounted directly on them.

As shown in FIGS. 1A and 1B, the bottom package 300 is mounted on the base 200 by a bonding process. The bottom package 300 is mounted on the base 200 using conductive structures 322. The bottom package 300 is a three-dimensional (3D) semiconductor package including a first semiconductor die 102, a second semiconductor die 132, a front-side redistribution layer (RDL) structure 316, a back-side redistribution layer (RDL) structure 366, through via (TV) interconnects 314 and the conductive structures 322. The conductive structures 322 are in contact with and electrically connected to the front-side RDL structure 316. In addition, the conductive structures 322 are electrically connected to the base 200. In some embodiments, the conductive structures 322 comprise a conductive ball structure such as a copper ball, a conductive bump structure such as a copper bump or a solder bump structure, or a conductive pillar structure such as a copper pillar structure.

In some embodiments, the bottom package 300 uses a chiplet architecture to split a large, single semiconductor die into multiple smaller functional semiconductor dies (called chiplets) fabricated in different technology nodes. Each chiplet may have improved device performance and fabrication yields. In addition, the bottom package 300 may have a reduced fabrication cost. As shown in FIG. 1A, the bottom package 300 includes at least two semiconductor dies, for example, the first semiconductor die 102 and the second semiconductor die 132 (also called chiplets 102 and 132) arranged side-by-side along the direction 100. Therefore, only one semiconductor die can be seen in the cross-sectional view along the direction 110. For example, only one semiconductor die 102 can be seen in the cross-sectional view as shown in FIG. 1B. The first semiconductor die 102 and the second semiconductor die 132 are disposed between the front-side RDL structure 316 and the back-side RDL structure 366. The first semiconductor die 102 has an active surface 102a and a backside surface 102b opposite to the active surface 102a. The second semiconductor die 132 has an active surface 132a and a backside surface 132b opposite to the active surface 112a. In some embodiments, the first semiconductor die 102 and the second semiconductor die 132 are fabricated by a flip-chip technology. The first semiconductor die 102 and the second semiconductor die 132 may be flipped to be disposed on the front-side RDL structure 316 opposite the conductive structures 322. In some embodiments, the first semiconductor die 102 and the second semiconductor die 132 each independently includes a system-on-chip (SoC) die, a logic device, a memory device, a radio frequency (RF) device, the like, or any combination thereof. For example, the first semiconductor die 102 and the second semiconductor die 132 may each independently include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (TO) die, a dynamic random access memory (DRAM) IP core, a static random-access memory (SRAM), a high bandwidth memory (HBM), the like, or any combination thereof. In some embodiments, the first semiconductor die 102 and the second semiconductor die 132 have different functions.

The first semiconductor die 102 and the second semiconductor die 132 may be fabricated in different technology nodes. In some embodiments, the first semiconductor die 102 has a first critical dimension (CD) and the second semiconductor die 132 has a second critical dimension different from the first critical dimension in order to provide different functionalities with a reduced cost. For example, the first critical dimension is narrower than the second critical dimension. Therefore, the first semiconductor die 102 and the second semiconductor die 132 may respectively arrange various interfaces to fulfill the requirements of internal and external signal transmission of the bottom package 300.

The front-side RDL structure 316 is disposed on the active surface 102a of the first semiconductor die 102 and the active surface 122a of the second semiconductor die 132. In other words, the first semiconductor die 102 and the second semiconductor die 132 are disposed on the front-side RDL structure 316. In addition, the front-side RDL structure 316 is disposed between front-side RDL structure 316 is disposed the first semiconductor die 102, the second semiconductor die 132 and the base 200. Pads 104 and 134 the active surface 102a and 132a of the first semiconductor die 102 and the second semiconductor die 132 are in contact with the front-side RDL structure 316. In some embodiments, the first semiconductor die 102 is electrically connected to the second semiconductor die 132 only using the vias 318 and the conductive traces 320 inside the front-side RDL structure 316. As shown in FIGS. 1A and 1B, the front-side RDL structure 316 may include one or more conductive traces 320 and one or more vias 318 disposed in one or more dielectric layers 317. In some embodiments, the conductive traces 320 and the vias 318 include a conductive material, such as metals comprising copper, gold, silver, or other applicable metals. The dielectric layers 317 may include extra-low K (ELK) dielectrics and/or ultra-low K (ULK) dielectric. In addition, the dielectric layers 317 may include epoxy. The first semiconductor die 102 and the second semiconductor die 132 are electrically connected to the base 200 using the vias 318 and the conductive traces 320 of the front-side RDL structure 316 and the corresponding conductive structures 322. It should be noted that the number of vias 318, the number of conductive traces 320 and the number of dielectric layers 317 shown in FIGS. 1A and 1B are only an example and is not a limitation to the present invention.

The through via (TV) interconnects 314 are disposed on the RDL structure 316 and beside the first semiconductor die 102 and the second semiconductor die 132 (FIGS. 2-7). As shown in FIG. 1B, the TV interconnects 314 are electrically connected to the vias 318 and the conductive traces 320 of the front-side RDL structure 316. In some embodiments, the TV interconnects 314 are electrically connected to the first semiconductor die 102 only using the vias 318 and the conductive traces 320 inside the front-side RDL structure 316. In some embodiments, the TV interconnects 314 are electrically connected to the second semiconductor die 132 by the front-side RDL structure 316 and the first semiconductor die 102.

As shown in FIGS. 1A and 1B, the bottom package 300 further includes a molding compound 312 disposed on and in contact with the front-side RDL structure 316. The molding compound 312 surrounds and is in contact with the first semiconductor die 102, the second semiconductor die 132 and the TV interconnects 314. In addition, the TV interconnects 314 pass through the molding compound 312. The backside surface 102b of the first semiconductor die 102 and the backside surface 132b of the second semiconductor die 132 may be exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the first semiconductor die 102 and the second semiconductor die 132, and then may be cured using a UV or thermally curing process. The molding compound 312 may be cured with a mold.

The bottom package 300 further includes a back-side redistribution layer (RDL) structure 366 disposed on the backside surface 102b of the first semiconductor die 102, the backside surface 132b of the second semiconductor die 132 and the TV interconnects 314 and opposite the front-side RDL structure 316. The back-side RDL structure 366 is in contact with the molding compound 312. The back-side RDL structure 366 is electrically connected to and in contact with both the TV interconnects 314 of the bottom package 300 and the top package 400. The front-side RDL structure 316 and the back-side RDL structure 366 are in contact with opposite ends of the TV interconnects 314, respectively. In other word, the first semiconductor die 102, the second semiconductor die 132 and the TV interconnects 314 are sandwiched between the front-side RDL structure 316 and the back-side RDL structure 366. In some embodiments, the back-side RDL structure 366 is electrically connected to the first semiconductor die 102 by the TV interconnects 314 and the front-side RDL structure 316. In some embodiments, the back-side RDL structure 366 is electrically connected to the second semiconductor die 132 by the TV interconnects 314, the front-side RDL structure 316 and the first semiconductor die 102.

In some embodiments, the back-side RDL structure 366 includes one or more conductive traces 370 and one or more vias 368 disposed in one or more dielectric layers 367. In some embodiments, the material of the conductive traces 370 may be similar to the material of the conductive traces 320. The material of the vias 368 may be similar to the material of the vias 318. In addition, the material of the dielectric layers 367 may be similar to the material of the dielectric layers 317. It should be noted that the number of vias 368, the number of conductive traces 370 and the number of dielectric layers 367 shown in FIGS. 1A and 1B are only an example and is not a limitation to the present invention. In some embodiments, edges 312E of the molding compound 312 are leveled with corresponding edges 316E of the front-side RDL structure 316 and corresponding edges 366E of the back-side RDL structure 366. Therefore, the edges 312 of the molding compound 312, the edges 316E of the front-side RDL structure 316 and the edges 366E of the back-side RDL structure 366 may collectively serve as package edges of the bottom package 300.

As shown in FIG. 1A, the bottom package 300 further includes an electronic component 330 mounted on the front-side RDL structure 316 opposite the first semiconductor die 102 and the second semiconductor die 132. In some embodiments, the electronic component 330 has pads 332 on it and is electrically connected to the conductive traces 320 of the front-side RDL structure 316. In some embodiments, the electronic component 330 is arranged between the conductive structures 322. The electronic component 330 can be free from being covered by a molding compound. In some embodiments, the electronic component 330 comprises integrated passive device (IPD) including a capacitor, an inductor, a resistor, or a combination thereof. In some embodiments, the electronic component 330 comprises DRAM dies.

As shown in FIGS. 1A and 1B, the top package 400 is stacked on the bottom package 300 by a bonding process. In some embodiments, the top package 400 comprises a memory package, such as a dynamic random access memory (DRAM) package or another applicable memory package. In some embodiments, the top package 400 includes a substrate 418, at least one semiconductor dies, for example, two semiconductor dies 402 and 404 that are stacked on the substrate 418, and conductive structures 422. In some embodiments, each of the semiconductor dies 402 and 404 comprises a dynamic random access memory (DRAM) die (e.g., a double data rate 4 (DDR4) DRAM die, a low-power DDR4 (LPDDR4) DRAM die, a double data rate (DDR) synchronous dynamic random access memory (SDRAM) die or the like) or another applicable memory die. In some other embodiments, the semiconductor dies 402 and 404 may comprise the same or different devices. In some embodiments, the top package 400 also comprises one or more passive components (not illustrated), such as resistors, capacitors, inductors, the like, or a combination thereof.

In this embodiment, as shown in FIGS. 1A and 1B, there are two semiconductor dies 402 and 404 mounted on the substrate 418 by a paste (not shown). The semiconductor dies 402 and 404 have corresponding pads 408 and 410 thereon, respectively. The pads 408 and 410 of the semiconductor dies 402 and 404 may be electrically connected to the substrate 418 using bonding wires 414 and 416, respectively. However, the number of stacked memory dies is not limited to the disclosed embodiment. Alternatively, the semiconductor dies 402 and 404 as shown in FIGS. 1A and 1B can be arranged side by side and mounted on the substrate 418 by a paste (not shown).

As shown in FIGS. 1A and 1B, the substrate 418 may comprise circuits 428 and contact pads 420 and 430 disposed in one or more extra-low K (ELK) and/or ultra-low K (ULK) dielectric layers (not shown). The contact pads 420 are disposed on the tops of the circuits 428 close to the top surface (die-attach surface) of the substrate 418. In addition, the bonding wires 414 and 416 are electrically connected to the corresponding contact pads 420. The contact pads 430 are disposed on the bottoms of the circuits 428 close to the bottom surface (bump-attach surface) of the substrate 418. The contact pads 430 are electrically connected to the corresponding contact pads 420. In some embodiments, the bonding wires 414 and 416, the contact pads 420 and 430 and the circuits 428 include a conductive material, such as metals comprising copper, gold, silver, or other applicable metals.

As shown in FIGS. 1A and 1B, the conductive structures 422 are disposed on the bottom surface of substrate 418 opposite the semiconductor dies 402 and 404. The conductive structures 422 may be arranged as an array and close to edges 400E1 and 400E3 of the top package 400 along the direction 100. Therefore, the conductive structures 422 may only be seen in the cross-sectional view along the direction 110 (FIG. 1B) and may not be seen in the cross-sectional view along the direction 100 (the conductive structures 422 are illustrated using dotted lines as shown in FIG. 1A). The conductive structures 422 are electrically connected to (or in contact with) the corresponding the contact pads 430 of the substrate 418 and the corresponding TV interconnects 314 of the bottom package 300. In some embodiments, the conductive structures 422 comprise a conductive ball structure such as a copper ball, a conductive bump structure such as a copper bump or a solder bump structure, or a conductive pillar structure such as a copper pillar structure.

In some embodiments, as shown in FIGS. 1A and 1B, the top package 400 further includes a molding material 412 covering the substrate 418, encapsulating the semiconductor dies 402 and 404 and the bonding wires 414 and 416. The top surface of the molding material 412 may serve as a top surface 400T of the top package 400. In some embodiments, the molding materials 312 and 412 may comprise the same or similar materials and fabrication processes.

FIGS. 2-7 are perspective bottom views (plan-views) of semiconductor package assemblies 500A-500F in accordance with some embodiments of the disclosure, showing the arrangements of interfaces of the semiconductor dies 102 and 132 and the through via (TV) interconnects 314 of the bottom package 300 and the arrangements of the conductive structures 422 of the top package 400 stacked on the bottom package 300. In some embodiments, the interfaces of the bottom package 300 used herein may include circuitry and input/output connections (e.g. the pads 104 and 134) disposed on the active surface 102a of the first semiconductor die 102 and the active surface 132a of the first semiconductor die 132. In some embodiments, the interfaces of the semiconductor dies 102 and 132 are used for signal transmission (data transmission) between the different semiconductor dies 102 and 132 of the same bottom package 300 or between the bottom package 300 and the top package 400. It is noted that FIGS. 2-7 only show the semiconductor dies 102 and 132, the molding material 312, the TV interconnects 314 of the bottom package 300 and the conductive structures 422 of the top package 400 for illustration, the remaining features may be shown in the schematic cross-sectional views of FIGS. 1A and 1B. It is appreciated that although some features are shown in some embodiments but not in other embodiments, these features may (or may not) exist in other embodiments whenever possible. For example, although each of the illustrated example embodiments shows specific arrangements of the interfaces of the semiconductor die 102, the TV interconnects and the conductive structures of the top package 400, any other combinations of the arrangements of the interfaces of the semiconductor die 102, the TV interconnects and the conductive structures of the top package 400 may also be used whenever applicable.

As shown in FIG. 2, the semiconductor dies 102 and 132 may have a rectangular plan-view shape. The semiconductor die 102 may have opposite edges 102E1 and 102E3 extending substantially along the direction 100 and opposite edges 102E2 and 102E4 substantially along the direction 110. The semiconductor die 132 may have opposite edges 132E1 and 132E3 extending substantially along the direction 100 and opposite edges 132E2 and 132E4 substantially along the direction 110. The opposite edges 102E1 and 102E3 of the semiconductor die 102 are beside and close to the opposite edges 132E1 and 132E3 of the semiconductor die 132, respectively. The edge 102E2 of the semiconductor die 102 connected between (or adjacent to) the edges 102E1 and 102E3 is close to the edge 132E2 of the semiconductor die 132 connected between the edges 132E1 and 132E3. The edge 102E4 of the semiconductor die 102 connected between the edges 102E1 and 102E3 is away from the edge 132E4 of the semiconductor die 132 connected between the edges 132E1 and 132E3.

As shown in FIGS. 1A, 1B and 2, the semiconductor die 102 and the semiconductor die 132 of the bottom package 300 of the semiconductor package assembly 500A may include interfaces arranged on the edges of the semiconductor dies 102 and 132. In some embodiments, the semiconductor die fabricated with a narrower critical dimension may be used to control the top package and include various interfaces for internal electrical connections between the different semiconductor dies of the same bottom package 300 and external electrical connections between the bottom package 300 and the top package 400. The semiconductor die fabricated with a wider critical dimension may only include an interface for internal electrical connections between the different semiconductor dies of the same bottom package 300.

For example, the semiconductor die 102 fabricated with a narrower critical dimension may include interfaces 102DDR-1, 102DDR-2, 102DDR-3, 102DDR-4 and 102DTD. In addition, the semiconductor die 132 fabricated with a wider critical dimension may include a single interface 132DTD. When the bottom package 300 is a SOC package, the top package 400 includes a double data rate 4 (DDR4) DRAM package, a low-power DDR4 (LPDDR4) DRAM package, a double data rate 5 (DDR5) DRAM package, a low-power DDR5 (LPDDR5) DRAM package or another applicable DRAM package. The interfaces 102DDR-1, 102DDR-2, 102DDR-3, 102DDR-4 may include double data rate 4 (DDR4) interfaces low-power DDR4 (LPDDR4) DRAM interfaces, double data rate 5 (DDR5) DRAM interfaces, low-power DDR5 (LPDDR5) DRAM interfaces or other applicable memory interfaces. The interfaces 102DDR-1, 102DDR-2, 102DDR-3, 102DDR-4 may be used for control the top package 400 (for example, transferring data to/from the memory controller in the semiconductor die 102). In addition, the interface 102DTD of the semiconductor die 102 and the interface 132DTD of the semiconductor die 132 may be die-to-die (DTD) interfaces including any suitable direct conductive electrical coupling between two different semiconductor dies 102 and 132 for data transmission. In some embodiments, the interface 102DTD of the semiconductor die 102 is electrically connected to the interface 132DTD of the semiconductor die 132 by the front-side RDL structure 316 rather than the interfaces 102DDR-1, 102DDR-2, 102DDR-3 and 102DDR-4.

In some embodiments, the conductive structures 422 of the top package 400 (e.g. the DDR4 DRAM package) are arranged according the given arrangement. For example, the conductive structures 422 of the top package 400 are arranged in two groups 422G1 and 422G2 (including a single column or multi-columns of the conductive structures 422) on the opposite edges 400E1 and 400E3 of the top package 400 along the direction 100, as shown in FIG. 2. Each group 422G1 and 422G2 of the conductive structures 422 may provide two data channels for the conductive structures 422. In order to reduce the length of routing paths between the top package 400 and the bottom package 300, the interfaces 102DDR-1, 102DDR-2, 102DDR-3, 102DDR-4 and the TV interconnects 314 of the bottom package 300 may be arranged corresponding to the arrangement of the conductive structures 422 of the top package 400. In some other embodiments, the top package 400 may further include additional conductive structures 422 (including a single column or multi-columns of the conductive structures 422) arranged on the edges 400E2 and 400E4 of the top package 400 for power transmission and grounding. In addition, the additional conductive structures 422 may be arranged according to the standards for the data rates of DDR. In some other embodiments, the distribution region of the conductive structures 422 (including the additional conductive structures 422) may have a hollow square shape.

As shown in FIGS. 1A and 2, the semiconductor dies 102 and 132 may be arranged side-by-side in the direction 100 parallel to the extending direction of the group 422G1 and 422G2 of the conductive structures 422. In some embodiments, the interfaces 102DDR-1 and 102DDR-2 of the semiconductor die 102 may be arranged side-by-side on the edge 102E1 corresponding to the group 422G1 of the conductive structures 422. The interfaces 102DDR-3 and 102DDR-4 of the semiconductor die 102 may be arranged side-by-side on the edge 102E3 corresponding to the group 422G2 of the conductive structures 422, as shown in FIGS. 1B and 2. In some embodiments, the interfaces 102DDR-1, 102DDR-2, 102DDR-3 and 102DDR-4 of the semiconductor die 102 partially overlap or fully overlap the corresponding groups 422G1 and 422G2 of the conductive structures 422 in a plan-view direction, as shown in FIG. 2. In addition, the interface 102DTD of the semiconductor die 102 may be arranged on the edge 102E2 connected to the edges 102E1 and 102E3. The interface 132DTD of the semiconductor die 132 is arranged on the edge 132E2 and close to the interface 102DTD of the semiconductor die 102. In some embodiments, no interfaces are arranged on the edges 132E1, 132E3 and 132E4 of the semiconductor die 132 fabricated with a wider critical dimension.

In some embodiments, the TV interconnects 314 are arranged in single column or multi-columns on opposite edges 312E1 and 312E3 of the molding compound 312 corresponding to the edges 102E1 and 102E3 where the interfaces 102DDR-1, 102DDR-2, 102DDR-3 and 102DDR-4 are arranged on. The edges 312E1 and 312E3 of the molding compound 312 may also serve as package edges 312E1 and 312E3 of the bottom package 300. In some embodiments, a distribution area 314A of the TV interconnects 314 is I-shaped in a plan-view as shown in FIG. 2. The TV interconnects 314 are arranged close to the interfaces 102DDR-1, 102DDR-2, 102DDR-3 and 102DDR-4 of the semiconductor die 102 to shorten the length of a routing path 316P of the front-side RDL structure 316 and the length of a routing path 366P of the back-side RDL structure 366. The routing path 316P between the interfaces 102DDR-1, 102DDR-2, 102DDR-3 and 102DDR-4 of the semiconductor die 102 and the corresponding TV interconnects 314 is composed of the conductive traces 320 and the vias 318 of the front-side RDL structure 316. In addition, the routing path 366P between the conductive structures 422 and the corresponding TV interconnects 314 is composed of the conductive traces 370 and the vias 368 of the back-side RDL structure 366. In some embodiments, there is no TV interconnect 314 arranged on edges 312E2 and 312E4 of the molding compound 312 (also serve as package edges 312E2 and 312E4 of the bottom package 300) corresponding to the edges 102E4 and 132E4 of the semiconductor die 102 without any interface arranged on, as shown in FIGS. 1A and 2. In some embodiments, the TV interconnects 314 are electrically connected to the interfaces 102DDR-1, 102DDR-2, 102DDR-3 and 102DDR-4 by the front-side RDL structure 316 rather than the interface 102DTD.

According to the arrangements of the interfaces 102DDR-1, 102DDR-2, 102DDR-3 and 102DDR-4, the through via (TV) interconnects 314 and the conductive structures 422, the semiconductor dies 402 and 404 of the top package 400 are electrically connected to the semiconductor die 102 by the conductive structures 422 of the top package 400 and the back-side RDL structure 366, the TV interconnects 314 and the front-side RDL structure 316 and the interfaces 102DDR-1, 102DDR-2, 102DDR-3 and 102DDR-4 of the bottom package 300. In addition, the semiconductor dies 402 and 404 of the top package 400 are electrically connected to the interfaces 102DDR-1, 102DDR-2, 102DDR-3 and 102DDR-4 of the bottom package 300. The semiconductor dies 402 and 404 of the top package 400 are electrically connected to the semiconductor die 102 by the conductive structures 422 of the top package 400 and the back-side RDL structure 366, the TV interconnects 314 and the front-side RDL structure 316 and the interfaces 102DDR-1, 102DDR-2, 102DDR-3, 102DDR-4, 102DTD and 132DTD of the bottom package 300.

The front-side redistribution layer (RDL) structure 316 is electrically connected to the interfaces 102DDR-1, 102DDR-2, 102DDR-3, 102DDR-4 and 102DTD of the semiconductor die 102. The back-side RDL structure 366 is electrically connected to the interfaces 102DDR-1, 102DDR-2, 102DDR-3, 102DDR-4 of the semiconductor die 102 by the TV interconnects 314 and the front-side RDL structure 316 rather than the interface 102DTD.

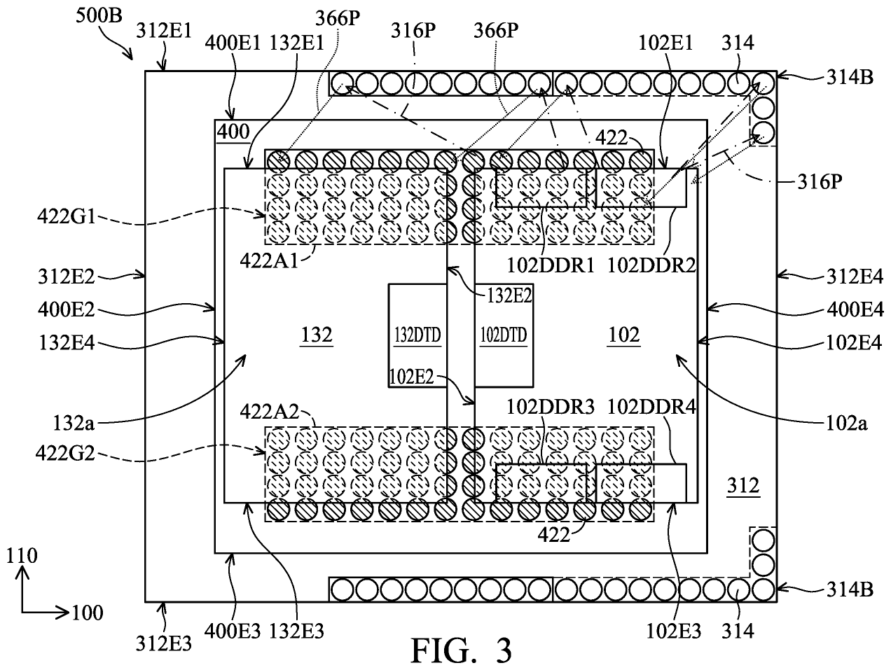

FIG. 3 is a perspective bottom view of the semiconductor package assembly 500B in accordance with some embodiments of the disclosure. Elements of the embodiments hereinafter, that are the same or similar as those previously described with reference to FIGS. 1A, 1B and 2, are not repeated for brevity. As shown in FIG. 3, the difference between the semiconductor package assembly 500A and the semiconductor package assembly 500B is that the semiconductor package assembly 500B includes the TV interconnects 314 of the bottom package 300 extending from the edge 312E1 (or the edge 312E3) to the edge 312E4 of the molding compound 312. The edge 312E4 is connected between the edges 312E1 and 312E3 and close to the semiconductor die 102 rather than the semiconductor die 132. In some embodiments, a distribution area 314B of the TV interconnects 314 is L-shaped in a plan-view as shown in FIG. 3. According to the arrangements of the TV interconnects 314, the length of the routing path 316P can be further reduced.

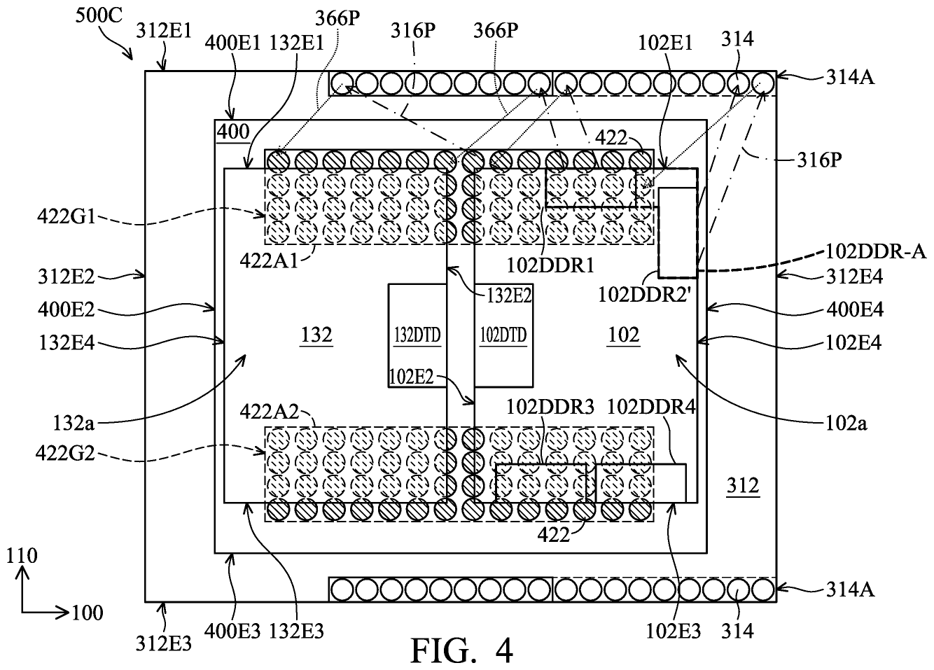

FIG. 4 is a perspective bottom view of the semiconductor package assembly 500C in accordance with some embodiments of the disclosure. Elements of the embodiments hereinafter, that are the same or similar as those previously described with reference to FIGS. 1A, 1B and 2-3, are not repeated for brevity. As shown in FIG. 4, the difference between the semiconductor package assembly 500A and the semiconductor package assembly 500C is that the semiconductor die 102 of the semiconductor package assembly 500C may have at least one interface 102DDR-2′ arranged on the edge 102E4 connected to the edges 102E1 and 102E3 and opposite the edge 102E2. Therefore, a distribution area 102DDR-A of the interfaces 102DDR-1 and 102DDR-2′ is L-shaped in a plan-view as shown in FIG. 4. In addition, the semiconductor dies 402 and 404 of the top package 400 may be electrically connected to the semiconductor dies 102 and 132 by the interface 102DDR-2′. In some embodiments, a distribution area (not shown) of the interfaces 102DDR-3 and 102DDR-4 may maintain to be I-shaped. Alternatively, the arrangement of the interfaces 102DDR-3 and 102DDR-4 may be similar to that of the interfaces 102DDR-1 and 102DDR-2′. For example, the interface 102DDR-4 may be arranged on the edge 102E4 and separated from the 102DDR-2′. Therefore, a distribution area (not shown) of the interfaces 102DDR-3 and 102DDR-4 may be L-shaped in a plan-view as shown in FIG. 4. In some embodiments, the semiconductor package assembly 500C may have any combination of I-shaped and L-shaped distribution areas of the interfaces 102DDR-1, 102DDR-2′ and the interfaces 102DDR-3, 102DDR-4. According to the arrangements of the interface 102DDR-2′ (or the interface 102DDR-4 arranged on the edge 102E4 in alternate embodiments), the flexibility of the floorplan design (including interface and/or routing design) of the semiconductor package assembly 500C for the channel arrangements of the memory package can be increased.

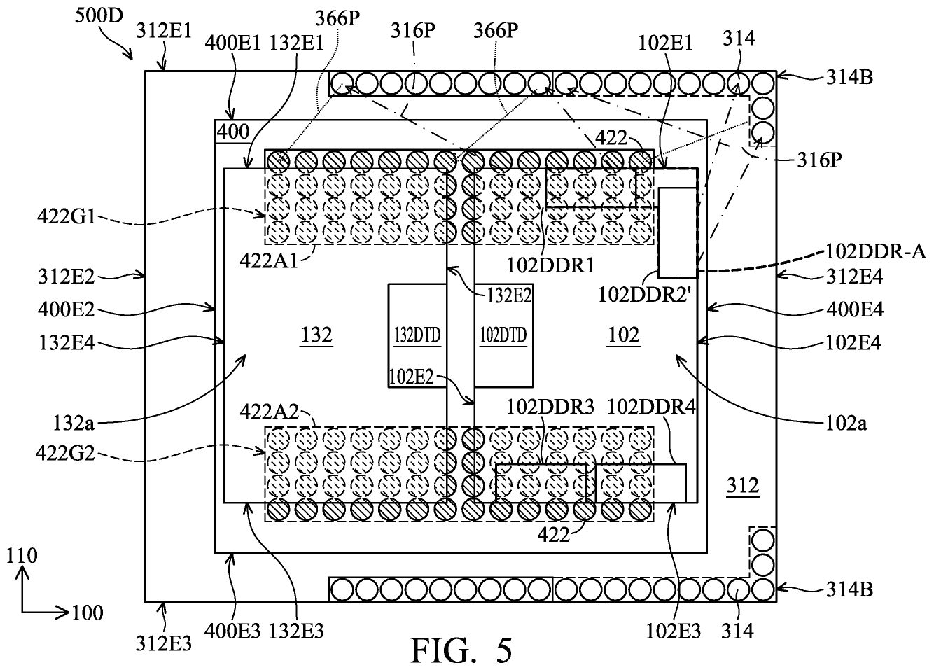

FIG. 5 is a perspective bottom view of the semiconductor package assembly 500D in accordance with some embodiments of the disclosure. Elements of the embodiments hereinafter, that are the same or similar as those previously described with reference to FIGS. 1A, 1B and 2-4, are not repeated for brevity. As shown in FIG. 5, the difference between the semiconductor package assembly 500D and the semiconductor package assembly 500C is that the semiconductor package assembly 500D arranges the TV interconnects 314 extending from the edge 312E1 to the edge 312E4 of the molding compound 312 to correspond to the interfaces 102DDR-1 and 102DDR-2′. In some embodiments, the distribution area 314B of the TV interconnects 314 is L-shaped in a plan-view as shown in FIG. 5. In some embodiments, a distribution area (not shown) of the interfaces 102DDR-3 and 102DDR-4 may be I-shaped. It is noted that the distribution area 314A of the TV interconnects 314 corresponding to the interfaces 102DDR-3 and 102DDR-4 may maintain to be I-shaped in a plan-view as shown in FIG. 5. Alternatively, the arrangement of the interfaces 102DDR-3 and 102DDR-4 may be similar to that of the interfaces 102DDR-1 and 102DDR-2′. For example, the interface 102DDR-4 may be arranged on the edge 102E4 and separated from the 102DDR-2′. Therefore, a distribution area (not shown) of the interfaces 102DDR-3 and 102DDR-4 may also be L-shaped in a plan-view as shown in FIG. 5. In some embodiments, the semiconductor package assembly 500D may have any combination of I-shaped and L-shaped distribution areas of the interfaces 102DDR-1, 102DDR-2′ and the interfaces 102DDR-3, 102DDR-4. According to the arrangements of the TV interconnects 314 corresponding to the interfaces 102DDR-1 and 102DDR-2′ (or corresponding to the interfaces 102DDR-3 and the interface 102DDR-4, which is arranged on the edge 102E4 in alternate embodiments), the length of the routing path 316P (between the interfaces 102DDR-1 and 102DDR-2′ and the TV interconnects 312) can be further reduced.

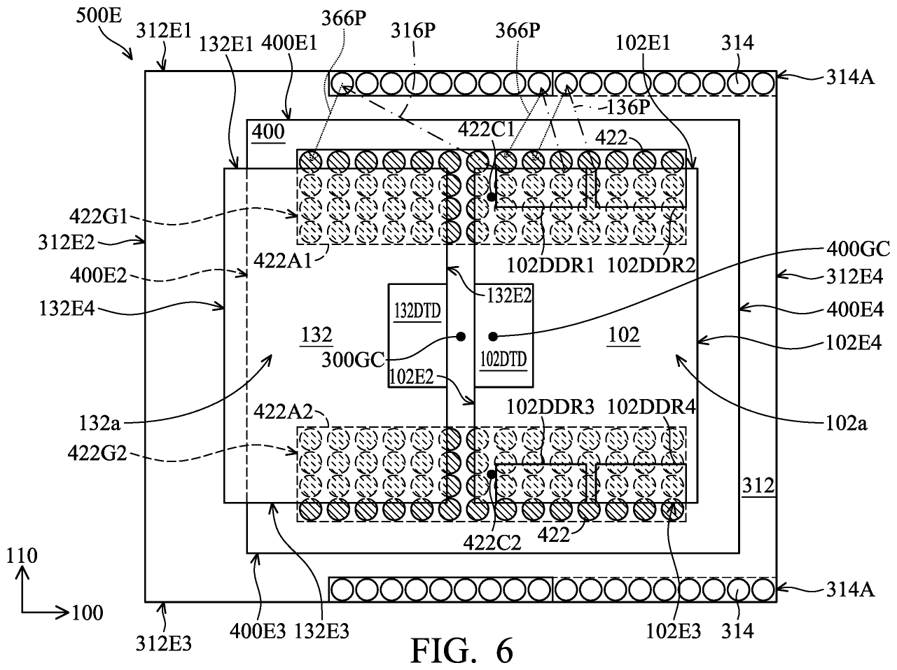

FIG. 6 is a perspective bottom view of the semiconductor package assembly 500E in accordance with some embodiments of the disclosure. Elements of the embodiments hereinafter, that are the same or similar as those previously described with reference to FIGS. 1A, 1B and 2-5, are not repeated for brevity. As shown in FIG. 6, the difference between the semiconductor package assembly 500E and the semiconductor package assembly 500C is that the semiconductor package assembly 500E has a geometric center 400GC of the top package 400 offset from a geometric center 300GC of the bottom package 300 in the direction 100. In some embodiments, the groups 422G1 and 422G2 of the conductive structures 422 are disposed in regions 422A1 and 422A2 of the top package 400. The region 422A1 may have a geometric center 422C1 closer to the semiconductor die 102 than the second semiconductor die 132 in a plan-view as shown in FIG. 6. The regions 422A2 a may have geometric center 422C2 closer to the semiconductor die 102 than the second semiconductor die 132 in a plan-view as shown in FIG. 6. In other words, the group 422G1 of the conductive structures 422 are disposed close to the corresponding interfaces 102DDR-1 and 102DDR-2, and the group 422G2 of the conductive structures 422 are disposed close to the corresponding interfaces 102DDR-3 and 102DDR-4. In a plan-view direction (perpendicular to the plane of the paper of FIG. 6), vertical projections (having the same shape as those of the interfaces 102DDR-1 and 102DDR-2) of the interfaces 102DDR-1 and 102DDR-2 of the semiconductor die 102 may be located within a vertical projection of the group 422G1 of the conductive structures 422. In addition, vertical projections (having the same shape as those of the interfaces 102DDR-3 and 102DDR-4) of the interfaces 102DDR-3 and 102DDR-4 of the semiconductor die 102 may be located within a vertical projection of the group 422G2 of the conductive structures 422. In some other embodiments, the interface 102DDR-2′ (FIG. 4) may be integrated in the semiconductor die 102 of the semiconductor package assembly 500E. In a plan-view direction of semiconductor package assembly 500E integrated with the interface 102DDR-2′, the overlapping area between the group 422G1 of the offset conductive structures 422 (FIG. 6) and the corresponding interfaces 102DDR-1 and 102DDR-2′ may be greater than the overlapping area between the group 422G1 of the conductive structures 422 and the corresponding interfaces 102DDR-1 and 102DDR-2 of the semiconductor package assembly 500C (in which the bottom package 300 and the top package 400 are concentric). According to the relative position between the bottom package 300 and the top package 400 of the semiconductor package assembly 500E, the length of the routing path 366P (between the TV interconnects 312 and the conductive structures 422) may be further reduced.

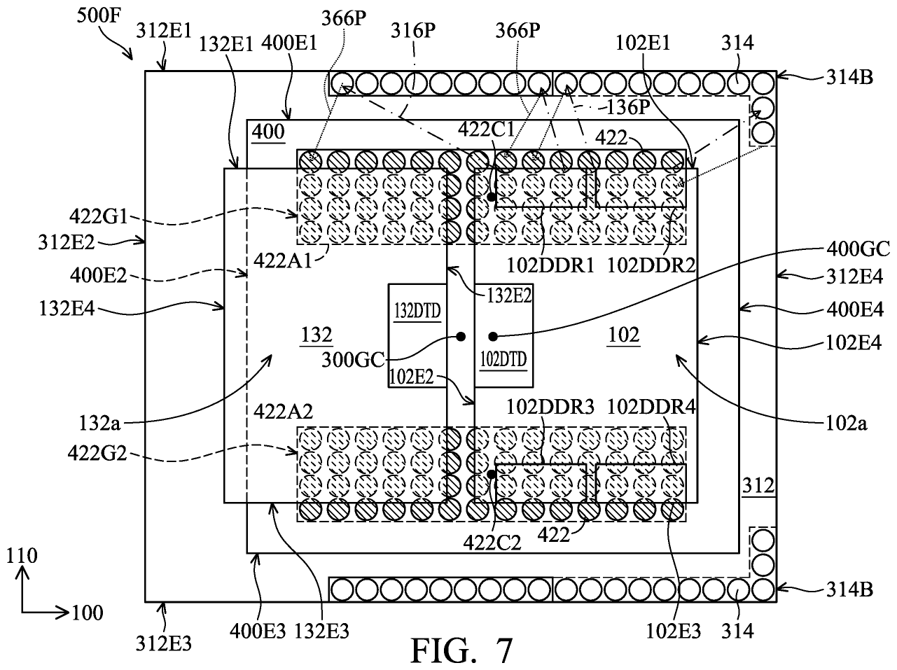

FIG. 7 is a perspective bottom view of the semiconductor package assembly 500F in accordance with some embodiments of the disclosure. Elements of the embodiments hereinafter, that are the same or similar as those previously described with reference to FIGS. 1A, 1B and 2-6, are not repeated for brevity. As shown in FIG. 7, the difference between the semiconductor package assembly 500F and the semiconductor package assembly 500E is that the semiconductor package assembly 500F arranges the TV interconnects 314 extending from the edge 312E1 (or the edge 312E4) to the edge 312E4 of the molding compound 312 to correspond to the interfaces 102DDR-1 and 102DDR-2 (or the interfaces 102DDR-3 and 102DDR-4). In some embodiments, the distribution area 314B of the TV interconnects 314 is L-shaped in a plan-view as shown in FIG. 7. According to the relative position between the bottom package 300 and the top package 400 and the arrangements of the TV interconnects 314 corresponding to the interfaces 102DDR-1, 102DDR-2, 102DDR-3 and 102DDR-4, the length of the routing path 316P and the length of the routing path 366P can be further reduced.

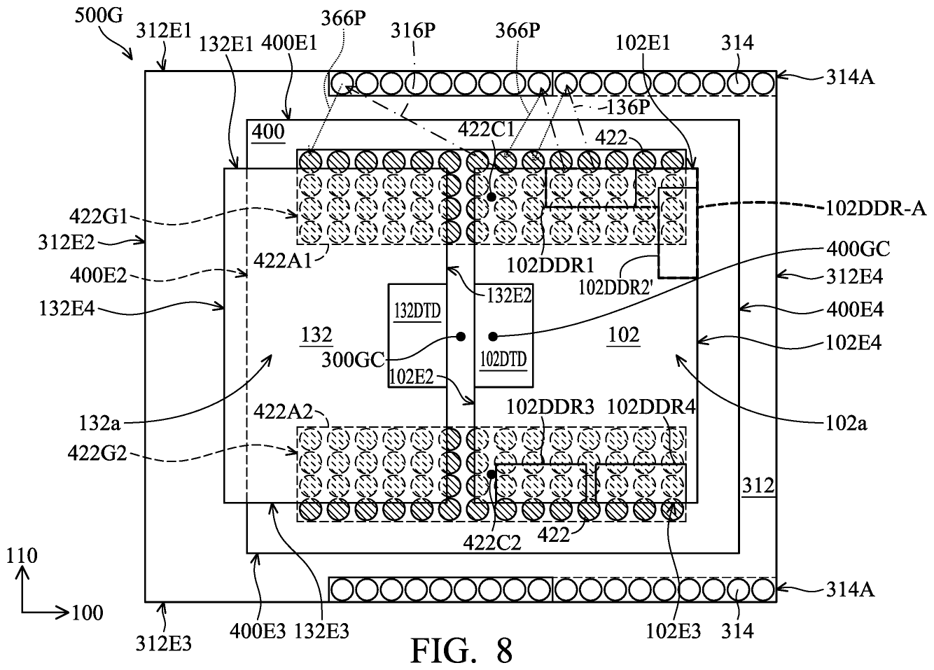

FIG. 8 is a perspective bottom view of the semiconductor package assembly 500G in accordance with some embodiments of the disclosure. Elements of the embodiments hereinafter, that are the same or similar as those previously described with reference to FIGS. 1A, 1B and 2-7, are not repeated for brevity. As shown in FIG. 8, the difference between the semiconductor package assembly 500G and the semiconductor package assembly 500E is that the semiconductor die 102 of the semiconductor package assembly 500G may have at least one interface 102DDR-2′ arranged on the edge 102E4 connected to the edges 102E1 and 102E3 and opposite the edge 102E2. Therefore, a distribution area 102DDR-A of the interfaces 102DDR-1 and 102DDR-2′ is L-shaped in a plan-view as shown in FIG. 8. In addition, the semiconductor dies 402 and 404 of the top package 400 may be electrically connected to the semiconductor dies 102 and 132 by the interface 102DDR-2′. In some embodiments, a distribution area (not shown) of the interfaces 102DDR-3 and 102DDR-4 may maintain to be I-shaped. Alternatively, the arrangement of the interfaces 102DDR-3 and 102DDR-4 may be similar to that of the interfaces 102DDR-1 and 102DDR-2′. For example, the interface 102DDR-4 may be arranged on the edge 102E4 and separated from the 102DDR-2′. Therefore, a distribution area (not shown) of the interfaces 102DDR-3 and 102DDR-4 may be L-shaped in a plan-view as shown in FIG. 8. In some embodiments, the semiconductor package assembly 500G may have any combination of I-shaped and L-shaped distribution areas of the interfaces 102DDR-1, 102DDR-2′ and the interfaces 102DDR-3, 102DDR-4. According to the arrangements of the interface 102DDR-2′ (or the interface 102DDR-4 arranged on the edge 102E4 in alternate embodiments), the flexibility of the floorplan design (including interface and/or routing design) of the semiconductor package assembly 500G for the channel arrangements of the memory package can be increased. According to the relative position between the bottom package 300 and the top package 400 and the arrangements of the TV interconnects 314 corresponding to the interfaces 102DDR-1, 102DDR-2′, 102DDR-3 and 102DDR-4, the length of the routing path 316P and the length of the routing path 366P can be further reduced.

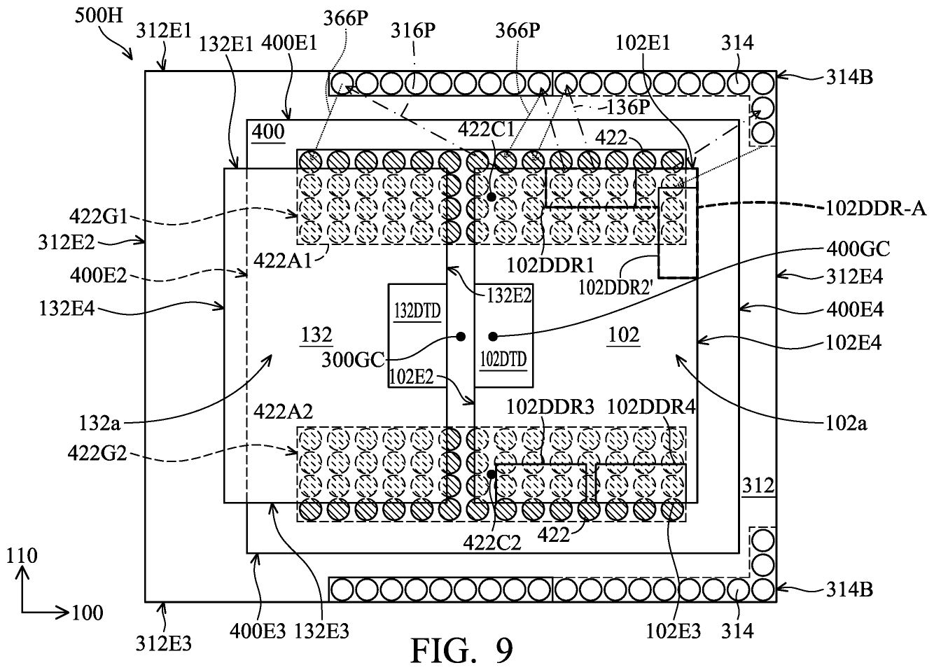

FIG. 9 is a perspective bottom view of the semiconductor package assembly 500H in accordance with some embodiments of the disclosure. Elements of the embodiments hereinafter, that are the same or similar as those previously described with reference to FIGS. 1A, 1B and 2-8, are not repeated for brevity. As shown in FIG. 9, the difference between the semiconductor package assembly 500H and the semiconductor package assembly 500G is that is that the semiconductor package assembly 500H arranges the TV interconnects 314 extending from the edge 312E1 to the edge 312E4 of the molding compound 312 to correspond to the interfaces 102DDR-1 and 102DDR-2′. In some embodiments, the distribution area 314B of the TV interconnects 314 is L-shaped in a plan-view as shown in FIG. 9. In some embodiments, a distribution area (not shown) of the interfaces 102DDR-3 and 102DDR-4 may be I-shaped. It is noted that the distribution area 314A of the TV interconnects 314 corresponding to the interfaces 102DDR-3 and 102DDR-4 may maintain to be I-shaped in a plan-view as shown in FIG. 9. Alternatively, the arrangement of the interfaces 102DDR-3 and 102DDR-4 may be similar to that of the interfaces 102DDR-1 and 102DDR-2′. For example, the interface 102DDR-4 may be arranged on the edge 102E4 and separated from the 102DDR-2′. Therefore, a distribution area (not shown) of the interfaces 102DDR-3 and 102DDR-4 may also be L-shaped in a plan-view as shown in FIG. 9. In some embodiments, the semiconductor package assembly 500H may have any combination of I-shaped and L-shaped distribution areas of the interfaces 102DDR-1, 102DDR-2′ and the interfaces 102DDR-3, 102DDR-4. According to the arrangements of the interface 102DDR-2′ (or the interface 102DDR-4 arranged on the edge 102E4 in alternate embodiments), the flexibility of the floorplan design (including interface and/or routing design) of the semiconductor package assembly 500H for the channel arrangements of the memory package can be increased. According to the relative position between the bottom package 300 and the top package 400 and the arrangements of the TV interconnects 314 corresponding to the interfaces 102DDR-1, 102DDR-2′, 102DDR-3 and 102DDR-4, the length of the routing path 316P and the length of the routing path 366P can be further reduced.

Embodiments provide a semiconductor package assembly, the semiconductor package assembly includes a bottom package (e.g., a SOC package) and a top package (e.g., a memory package) stacked on the bottom package. The bottom package includes two semiconductor dies (e.g., logic dies) fabricated with different critical dimensions. The first semiconductor die having a narrower critical dimension is used to control the top package and includes internal and external interfaces for internal electrical connections between the different semiconductor dies of the same bottom package and external electrical connections between the bottom package and the top package. The second semiconductor die fabricated with a wider critical dimension may only include an internal interface for internal electrical connections between the different semiconductor dies of the same bottom package. In some embodiments, the semiconductor dies of the bottom package are arranged side-by-side in the direction (e.g., the direction 100) parallel to the extending direction of the groups of the conductive structures of the top package. The external interfaces used for data transmission between the top package and the bottom package are arranged on opposite edges of the first semiconductor die corresponding to the groups of the conductive structures of the top package. In some embodiments, the internal interface of the first semiconductor die used for data transmission between the two semiconductor dies is arranged on another edge connected between the opposite edges of the first semiconductor die and close to the internal interface of the second semiconductor die. Compared with the conventional semiconductor package in which the external interfaces are arranged on each semiconductor dies of the bottom package, the routing path between the bottom package and the top package can be reduced. In addition, the signal delay problem can be improved. In some embodiments, the TV interconnects are arranged on package edges corresponding to the external interfaces and have an I-shape or an L-shape in a plan-view. In some embodiments, the adjacent internal interfaces are arranged on adjacent edges and have an L-shaped arrangement in order to increase the flexibility of the floorplan design. In some embodiments, the geometric center of the top package is offset from the geometric center of the bottom package, so that the conductive structures can be located closer to the external interfaces of the first semiconductor die. The length of the routing paths between the bottom package and the top package can be further reduced.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a first semiconductor die and a second semiconductor die arranged side-by-side, wherein the first semiconductor die comprises:
a first interface arranged on a first edge of the first semiconductor die; and
a second interface arranged on a second edge of the first semiconductor die that is close to the second semiconductor die and connected to the first edge; and
a third semiconductor die stacked on the first semiconductor die and the second semiconductor die, wherein the third semiconductor die is electrically connected to the first semiconductor die by the first interface, and wherein the first semiconductor die is electrically connected to the second semiconductor die by the second interface.

2. The semiconductor package assembly as claimed in claim 1, wherein the first semiconductor die has a first critical dimension and the second semiconductor die has a second critical dimension, wherein the first critical dimension is narrower than the second critical dimension.

3. The semiconductor package assembly as claimed in claim 1, wherein the third semiconductor die is electrically connected to the second semiconductor die by the first interface and the second interface.

4. The semiconductor package assembly as claimed in claim 1, wherein the first semiconductor die comprises a third interface arranged on a third edge connected to the first edge and opposite the second edge, wherein the third semiconductor die is electrically connected to the first semiconductor die and the second semiconductor die by the third interface.

5. The semiconductor package assembly as claimed in claim 1, wherein the first semiconductor die comprises a fourth interface arranged on a fourth edge connected to the second edge and opposite the first edge, wherein the third semiconductor die is electrically connected to the first semiconductor die and the second semiconductor die by the fourth interface.

6. The semiconductor package assembly as claimed in claim 1, further comprising:
a front-side redistribution layer (RDL) structure electrically connected to the first interface and the second interface of the first semiconductor die, wherein the first semiconductor die and the second semiconductor die are disposed on the front-side RDL structure; and
through via (TV) interconnects disposed beside the first semiconductor die and the second semiconductor die and electrically connected to the front-side RDL structure.

7. The semiconductor package assembly as claimed in claim 6, wherein the TV interconnects are electrically connected to the first interface by the front-side RDL structure rather than the second interface.

8. The semiconductor package assembly as claimed in claim 6, further comprising:
a molding compound surrounding the first semiconductor die and the second semiconductor die, wherein the TV interconnects pass through the molding compound and are arranged on a fifth edge of the molding compound corresponding to the first edge of the first semiconductor die.

9. The semiconductor package assembly as claimed in claim 8, wherein the TV interconnects are arranged extending to a sixth edge of the molding compound and close to the first semiconductor die.

10. The semiconductor package assembly as claimed in claim 9, wherein a distribution area of the TV interconnects is L-shaped in a plan-view.

11. The semiconductor package assembly as claimed in claim 6, further comprising:
a back-side redistribution layer (RDL) structure disposed between the front-side RDL structure and the third semiconductor die, wherein the back-side RDL structure is electrically connected to the first interface of the first semiconductor die by the TV interconnects and the front-side RDL structure.

12. The semiconductor package assembly as claimed in claim 11, further comprising:
a fan-out package comprising the first semiconductor die, the second semiconductor die, the front-side RDL structure and the back-side RDL structure; and
a memory package comprising the third semiconductor die and stacked on the fan-out package, wherein the memory package comprises conductive structures arranged in groups and disposed on a seventh edge of the memory package corresponding to the first edge of the first semiconductor die.

13. The semiconductor package assembly as claimed in claim 12, wherein one of the groups of the conductive structures is disposed in a region of the memory package, wherein the region has a geometric center closer to the first semiconductor die than the second semiconductor die in a plan-view.

14. A semiconductor package assembly, comprising:
a fan-out package, comprising:
a first semiconductor die and a second semiconductor die arranged side-by-side, wherein the first semiconductor die comprises:
a first interface arranged on a first edge of the first semiconductor die; and
a second interface arranged on a second edge of the first semiconductor die that is close to the second semiconductor die and adjacent to the first edge; and
through via (TV) interconnects disposed beside the first semiconductor die and the second semiconductor die and arranged on a first package edge of the fan-out package corresponding to the first edge of the first semiconductor die; and
a memory package stacked on the fan-out package and electrically connected to the second semiconductor die by the TV interconnects, the first interface and the second interface.

15. The semiconductor package assembly as claimed in claim 14, wherein the first semiconductor die has a first critical dimension and the second semiconductor die has a second critical dimension, wherein the first critical dimension is narrower than the second critical dimension.

16. The semiconductor package assembly as claimed in claim 14, wherein the first semiconductor die comprises a third interface arranged on a third edge adjacent to the first edge and opposite the second edge, wherein the memory package is electrically connected to the second semiconductor die by the TV interconnects, the second interface and the third interface.

17. The semiconductor package assembly as claimed in claim 14, wherein the first semiconductor die comprises a fourth interface arranged on a fourth edge adjacent to the second edge and opposite the first edge, wherein the memory package is electrically connected to the first semiconductor die and the second semiconductor die by the TV interconnects, the second interface and the fourth interface.

18. The semiconductor package assembly as claimed in claim 14, further comprising:
a front-side redistribution layer (RDL) structure electrically connected to the first interface and the second interface of the first semiconductor die, wherein the first semiconductor die and the second semiconductor die are disposed on the front-side RDL structure; and
a back-side redistribution layer (RDL) structure disposed between the front-side RDL structure and the memory package, wherein the back-side RDL structure is electrically connected to the first interface of the first semiconductor die by the TV interconnects and the front-side RDL structure rather than the second interface.

19. The semiconductor package assembly as claimed in claim 14, wherein a distribution area of the TV interconnects has a shape comprising an I-shape or an L-shape in a plan-view.

20. The semiconductor package assembly as claimed in claim 14, wherein the memory package comprises conductive structures arranged in a region of the memory package, wherein the region has a geometric center closer to the first semiconductor die than the second semiconductor die in a plan-view.

21. A semiconductor package assembly, comprising:
a bottom package, comprising:
a first semiconductor die and a second semiconductor die arranged side-by-side, wherein the first semiconductor die comprises:
a first interface arranged on a first edge of the first semiconductor die;
a second interface arranged on a second edge of the first semiconductor die that is close to the second semiconductor die and connected to the first edge; and
a third interface arranged on a third edge connected to the first edge and opposite the second edge; and
through via (TV) interconnects disposed beside the first semiconductor die and the second semiconductor die and arranged on a first package edge of the first package corresponding to the first edge of the first semiconductor die; and
a top package stacked on the bottom package and electrically connected to the first interface of the first semiconductor die by the TV interconnects and the first interface rather than the second interface.

22. The semiconductor package assembly as claimed in claim 21, wherein the top package is electrically connected to the second semiconductor die by the TV interconnects, the second interface and the third interface.

23. The semiconductor package assembly as claimed in claim 21, wherein the bottom package further comprises:
a front-side redistribution layer (RDL) structure provided for the first semiconductor die and the second semiconductor die disposed on the front-side RDL structure, wherein the second interface of the first semiconductor die is electrically connected to a fourth interface of the second semiconductor die by the front-side RDL structure rather than the first interface.

24. The semiconductor package assembly as claimed in claim 21, wherein a distribution area of the TV interconnects has a shape comprising an I-shape or an L-shape in a plan-view.

25. The semiconductor package assembly as claimed in claim 21, wherein the top package comprises conductive structures arranged in a region of the memory package, wherein the region has a geometric center closer to the first semiconductor die than the second semiconductor die in a plan-view.
